(19) United States
(12) Patent Application Publication
(10) Pub. No.: US 2006/0291153 A1
(43) Pub. Date: Dec. 28, 2006

(54) Plasma display module

(76) Inventor: Sung-Won Bae, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/475,005

(22) Filed: Jun. 27, 2006

(30) Foreign Application Priority Data
Jun. 28, 2005 (KR) 10-2005-0056054
Jun. 28, 2005 (KR) 10-2005-0056055

(51) Int. Cl. H05K 5/00; G06F 1/16; H05K 7/00

(52) U.S. Cl. 361/681; 361/679

(57) ABSTRACT

A plasma display module includes a plasma display panel, a chassis for supporting the plasma display panel, a driving circuit substrate which is located on a side of the chassis and includes a plurality of circuit devices that generate electrical signals to drive the plasma display panel and a heat dissipating sheet located on a surface of the heat generation unit to dissipate heat generated from the heat generation unit.

### BACKGROUND OF THE INVENTION

1. Field of the Invention

The present invention relates to a plasma display module. More particularly, the present invention relates to a plasma display module having improved heat dissipation.

2. Description of the Related Art

A plasma display module is a flat panel display device that displays an image using a gas discharge. Plasma display modules have received much attention, since they can be manufactured in large, thin sizes, have wide viewing angles and can display high quality images.

A plasma display module may include a plasma display panel (PDP) having a first panel and a second panel, a chassis that supports the PDP and a driving circuit substrate located on the rear surface of the chassis to drive the PDP. A large amount of heat may be generated from the plasma display module when the PDP is operating. In the plasma display module, a heat generating unit that generates a relatively large amount of heat may include the PDP and circuit devices. The circuit devices may include ordinary circuit devices and special circuit devices, i.e., heat generating circuit devices. An example of the heat generating circuit devices is an integrated circuit chip (ICC). If heat is not quickly dissipated from the ICC, not only may the ICC be degraded, but performance of the driving circuit substrate may also be reduced.

The plasma display module employs a discharge mechanism in which a high voltage is applied to discharge cells to cause a discharge to generate light. Therefore, a large amount of heat may be generated by the discharge cells in the PDP when the PDP is driven. If heat is not quickly dissipated, the PDP may not reliably operate, which may result in degraded image quality and shortened lifetime.

### SUMMARY OF THE INVENTION

The present invention is therefore directed to a plasma display module, which substantially overcomes one or more of the disadvantages of the related art.

It is therefore a feature of an embodiment of the present invention to provide a plasma display module having an improved heat dissipation performance.

It is another feature of an embodiment of the present invention to provide a plasma display panel that can avoid an electrical short or malfunction of circuit devices while maintaining the heat dissipation performance of the plasma display panel.

At least one of the above and other features and advantages of the present invention may be realized by providing a plasma display module including a plasma display panel, a chassis for supporting the plasma display panel, a driving circuit substrate including a plurality of circuit devices located on a side of the chassis to generate electrical signals for driving the plasma display panel, and a thermally conductive heat dissipating sheet located on a surface of a heat generation unit to dissipate heat generated from the heat generation unit.

The heat dissipating sheet may contain low-molecular-weight siloxane in a content of about 5,000 wt ppm or less, or may contain no low-molecular-weight siloxane.

The heat dissipating sheet may include a first heat dissipating portion having a thermally conductive layer on a surface of the heat generation unit and an electrically insulating layer surrounding at least a portion of the thermal conductive layer. The electrically insulating layer may have an electrical insulating resistance of at least about 1×10¹⁰ ohm·cm. The first heat dissipating portion may further include an adhesive layer to increase adherence to the heat generation unit. The first heat dissipating portion may have a thermal conductivity of at least about 0.1 W/mK. The first heat dissipating portion may include silicone.

The heat dissipating sheet may further include a second heat dissipating portion on the first heat dissipating portion having a different flexibility and thermal conductivity from the first heat dissipating portion. The second heat dissipating portion may have a thermal conductivity of at least about 0.5 W/mK. The first heat dissipating portion may have higher flexibility that the second heat dissipating portion. The second heat dissipating portion may include a cushion layer and a thermally conductive layer on the cushion layer.

The dissipation unit maybe the plasma display panel. The heat dissipating sheet may be between the plasma display panel and the chassis.

The heat dissipating unit may be a heat generating circuit device. The heat dissipating sheet may be between a portion of the driving circuit substrate having the heat generating circuit devices and the chassis or between the heat generating circuit devices and the chassis.

The plasma display module may include a signal transmitting member for transmitting an electrical signal between the plasma display panel and the driving circuit substrate, the signal transmitting member including an electronic device, wherein the heat generation unit is the electronic device. The signal transmitting member may be a tape carrier package and the electronic device is a tape carrier package integrated circuit. The plasma display module may further include a cover plate covering the electronic device, wherein the heat dissipating sheet is between the cover plate and the electronic device.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates an exploded perspective view of a plasma display module according to an embodiment of the present invention;

FIG. 2 illustrates a cross-sectional view taken along line II-II of FIG. 1;

FIG. 3 illustrates a horizontal cross-sectional view of first heat dissipating sheets of FIG. 2;

FIG. 4 illustrates a horizontal cross-sectional view of second heat dissipating sheets of FIG. 2;

FIG. 5 illustrates a modified version of the plasma display module of FIG. 1 according to an embodiment of the present invention;

FIG. 6 illustrates cross-section of a plasma display module according to another embodiment of the present invention; and

FIG. 7 illustrates a modified version of the plasma display module of FIG. 6 according to another embodiment of the present invention.

### DETAILED DESCRIPTION OF THE INVENTION

Korean Patent Application Nos. 10-2005-0056054, filed on Jun. 28, 2005, and 10-2005-0056055, filed on Jun. 28, 2005, in the Korean Intellectual Property Office, and entitled: “Plasma Display Module,” are incorporated by reference herein in their entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration.

It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

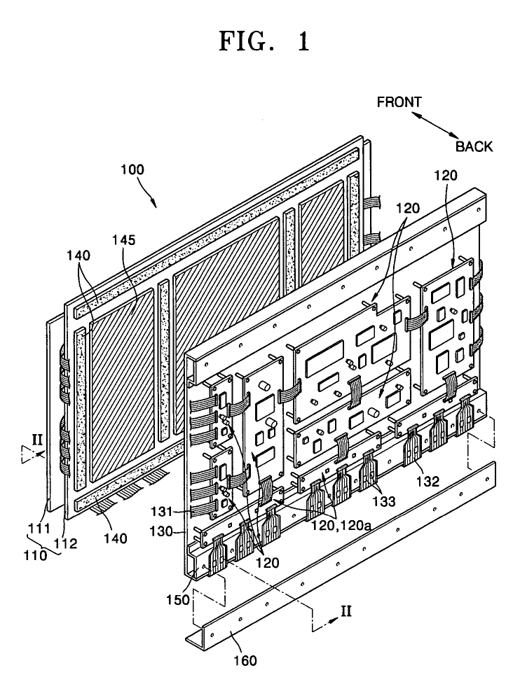

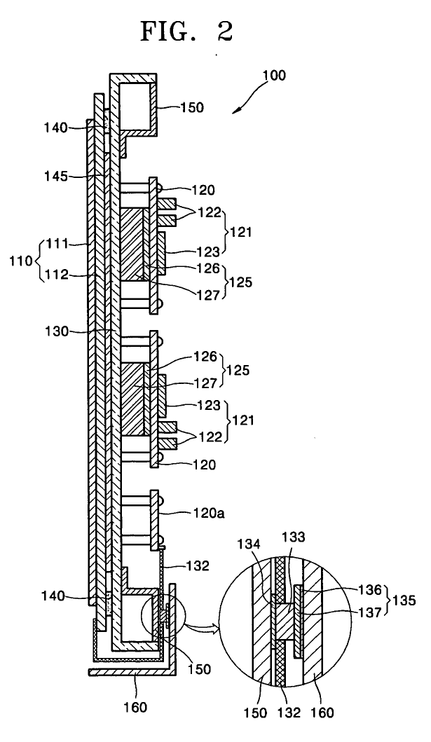

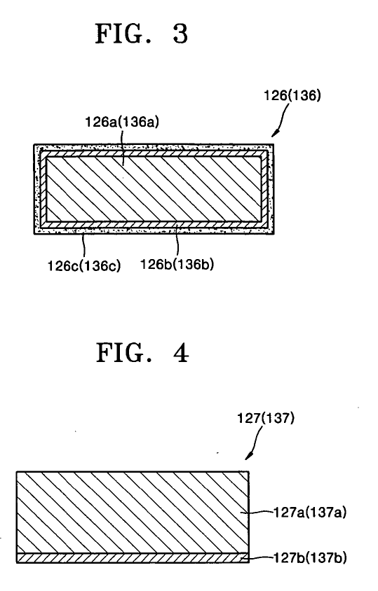

FIG. 1 illustrates an exploded perspective view of a plasma display module 100 according to an embodiment of the present invention, and FIG. 2 illustrates a cross-sectional view taken along line II-II of FIG. 1. FIG. 3 illustrates a horizontal cross-sectional view of first heat dissipating sheets of FIG. 2. FIG. 4 illustrates a horizontal cross-sectional view of second heat dissipating sheets of FIG. 2.

The plasma display module 100 may include a PDP 110 where an image is displayed. The PDP 110 can be any of various types of PDPs. For example, the PDP 110 may be a three-electrode type alternating current surface discharge PDP. In this case, the PDP 110 may include a first panel 111 and a second panel 112. More specifically, the first panel 111 may include (not shown) a plurality of sustain electrode pairs including a common electrode and a scanning electrode having a strip shape, a first dielectric layer covering the sustain electrode pair and a protection layer coated on the surface of the first dielectric layer. The second panel 112 facing the first panel 111 may include (not shown) a plurality of address electrodes crossing the sustain electrode pairs on the second substrate, a second dielectric layer covering the address electrodes, barrier ribs formed on the second dielectric layer to prevent cross-talk and to define discharge cells where a discharge takes place, and red, green and blue phosphor layers on inner walls of the discharge cells defined by the barrier ribs. The discharge cells may correspond to each region where the sustain electrode pair and the address electrode cross each other, and a discharge gas may fill the discharge cells.

A chassis 130 may be located on a back of the PDP 110. The chassis 130 may prevent the temperature of the PDP 110 from rising beyond a predetermined level by dissipating heat transferred from the PDP 110 and may prevent the PDP 110 from being deformed by heat and/or damaged by an external impact. The chassis 130 must have sufficient strength for supporting the PDP 110 in order to prevent the PDP 110 from being deformed by heat and damaged by an external impact. To reinforce the strength of the chassis 130, the plasma display module 100 may include a reinforcing member 150 on the chassis 130. The plasma display module 100 may include an adhesion member 140, e.g., double-sided tape, between the PDP 110 and the chassis 130 to attach the PDP 110 to the chassis 130.

At least one driving circuit substrate 120 may be located on a surface of the chassis 130 to drive the PDP 110. The driving circuit substrate 120 may include various circuit devices 121 for applying a voltage signal to display an image or for supplying a voltage to drive the PDP 110.

The circuit devices 121 may include heat generating circuit devices 123 that generate a relatively large amount of heat and ordinary circuit devices 122 that a generate relatively small amount of heat. The heat generating circuit devices 123 may include, e.g., an intelligent power module (IPM) device which may include active devices, e.g., semiconductor chips, etc., formed on a conductive layer having a predetermined pattern, and passive devices, e.g., individual resistors, capacitors, etc.

The plasma display module 100 may further include signal transmitting members that are electrically connected to the plasma display panel 110 to transmit signals. The signal transmitting members may be flexible printed cables (FPCs), tape carrier packages (TCPs) and/or chip on films (COFs). In the particular embodiment show in FIG. 1, TCPs 132 may be used for transmitting electrical signals between the address electrodes (not shown) and the address electrode driving board 120a. A TCP integrated circuit (TCP IC) 133 may be mounted on the TCP 132. FPCs 131 may be located on both sides of the chassis 130.

A cover plate 160 may be located on the TCP IC 133. The cover plate 160 may be formed of a material having a high thermal conductivity, e.g., an aluminium alloy. By the above structure, heat generated from the TCP IC 133 may be transferred away from the reinforcing member 150, and at the same time, damage to the TCP IC 133 may be prevented.

A heat dissipating sheet 145 may be located between the plasma display panel 110 and the chassis 130 to uniformly transfer heat generated by the PDP 110 to the chassis 130. The heat dissipating sheet 145 may prevent heat accumulation in the PDP 110 when the PDP 110 is operating. The heat dissipating sheet 145 may be formed of a material having a high thermal conductivity, e.g., graphite, aluminium, copper, thermally conductive resin, etc.

Referring to FIG. 2, a first heat dissipating sheet 125 for dissipating heat generated from the heat generating circuit devices 123 may be interposed between the driving circuit substrate 120 and the chassis 130. The first heat dissipating sheet 125 may be located between the driving circuit substrate 120 on which the heat generating circuit devices 123 are mounted and the chassis 130. In this configuration, heat generated from the heat generating circuit devices 123 may be transferred to the first heat dissipating sheet 125 through the driving circuit substrate 120. The heat transferred to the first heat dissipating sheet 125 may then be transferred to the chassis 130, which has a relatively low temperature, and eventually dissipated into the surrounding environment.

A second heat dissipating sheet 135 for dissipating heat from the TCP IC 133 may be included between the TCP IC 133 and the cover plate 160. However, the present invention is not limited thereto, and the cover plate 160 may not be included in the plasma display module. The second heat dissipating sheet 135 may transfer heat generated from the TCP IC 133 to the cover plate 160. The second heat dissipating sheet 135 may also prevent the TCP IC 133 from being damaged when the cover plate 160 is mechanically coupled to the reinforcing member 150 using, e.g., bolts.

Maintaining uniform contact between the TCP IC 133 and the reinforcing member 150 may be difficult due to surface roughness of the TCP IC 133 or the reinforcing member 150. To solve this problem, as depicted in FIG. 2, a fluid substance 134, e.g., a thermal conductive grease, etc., may be located between the TCP IC 133 and the reinforcing member 150.

The first and the second heat dissipating sheets 125 and 135 may respectively include first heat dissipation units 126 and 136 and second heat dissipation units 127 and 137 having different flexibility and thermal conductivity. The first heat dissipation units 126 and 136 may be made of a material having high thermal conductivity, high thermal stability, high flexibility, and low reactivity, e.g., silicone. Heat dissipation units formed of silicone generally include low-molecular-weight siloxane. When the low-molecular-weight siloxane content is too high, low-molecular-weight siloxane may bleed out of the surface of the silicone in an oil form (an oil bleeding phenomenon). When the low-molecular-weight siloxane content is not high enough to cause oil bleeding, but higher than a critical level, the low-molecular-weight siloxane may directly vaporize out of the silicone. The low-molecular-weight siloxane that bleeds or vaporizes out of the silicone may adhere to parts of the plasma display module in a silica form. The silica adhering to the circuit devices may cause a malfunction of the circuit devices due to an insulating characteristic of the silica.

Therefore, the first heat dissipation units 126 and 136 may have the low-molecular-weight siloxane content of less than a critical level, e.g., about 5,000 wt ppm. Thus, when a large amount of heat is generated from the heat generating circuit devices 123, vaporization of the low-molecular-weight siloxane in the first heat dissipation units 126 and 136 can be prevented. Also, although the low-molecular-weight siloxane may still vaporize and form an electric insulating silica layer (not shown) adhering on various circuit devices 121 mounted on the driving circuit substrate 120, the build-up of the electric insulating silica layer to a thickness that can cause a malfunction of the circuit devices 121 can be prevented. However, the present invention is not limited thereto, and the first heat dissipation units 126 and 136 can be formed of a material that does not include the low-molecular-weight siloxane to solve the above mentioned problem.

The first heat dissipation units 126 and 136 may have a thermal conductivity of at least 0.1 W/mK. When the thermal conductivity of the first heat dissipation units 126 and 136 is lower than 0.1 W/mK, heat may not be effectively dissipated, but instead may accumulate in the heat generation unit causing the degradation of the TCP IC 133 and the heat generating circuit devices 123.

Referring to FIG. 3, the first heat dissipation units 126 and 136 may respectively include thermally conductive layers 126a and 136a and electrically insulating layers 126b and 136b that surround the thermally conductive layers 126a and 136a. In general, various circuit devices 121 may be mounted on a surface of the driving circuit substrate 120 and, on the other surface, electrical wires (not shown) of the circuit devices 121 protruding through the driving circuit substrate 120 may be soldered. The electrically insulating layers 126b and 136b contact the soldered parts (not shown) of the first heat dissipation units 126 and 136, without causing a short circuit. The electrical insulating layers 126b and 136b may have an electrical insulation resistance of at least about 1×10¹⁰ ohm·cm, and, more preferably, at least about 1×10¹⁵ ohm·cm.

However, the present invention is not limited thereto, that is, the first heat dissipation units 126 and 136 may include only the thermally conductive layers 126a and 136a without the electric insulating layers 126b and 136b.

The thermal conductive layers 126a and 136a may include adhesive layers 126c and 136c. The adhesive layers 126c and 136c may increase the adherence of the first heat dissipation units 126 and 136 to the heat generating circuit devices 123 and 133. Accordingly, potential delay of installation arising from sliding of the first and second heat dissipating sheets 125 can be prevented. However, the present invention is not limited thereto, i.e., the first heat dissipation units 126 and 136 may not include the adhesive layers 126c and 136c.

The first heat dissipation units 126 and 136 may have higher flexibility than second heat dissipating sheets 127 and 137. As a result, when the surface of the driving circuit substrate 120 or the cover plate 160 is not smooth, the first heat dissipation units 126 and 136 may closely contact to the surface of the driving circuit substrate 120 or the cover plate 160, thereby increasing heat dissipation performance. The first heat dissipation units 126 and 136 may be as thin as possible within a predetermined range so that the first heat dissipation units 126 and 136 can tightly contact the driving circuit substrate 120 or the cover plate 160. This is because, when the thermal conductivity of the first heat dissipation units 126 and 136 is lower than that of the second heat dissipating sheets 127 and 137, the overall heat transfer rate of the first and second heat dissipating sheets 125 and 135 may be reduced.

The second heat dissipating sheets 127 and 137 may have a thermal conductivity of at least 0.5 W/mK. As a result, heat transferred to the first heat dissipation units 126 and 136, which may have a low thermal conductivity due to the requirement of flexibility, can be rapidly dissipated through the second heat dissipating sheets 127 and 137. That is, the reduced heat transfer rate caused by the relatively low thermal conductivity of the first heat dissipation units 126 and 136 can be compensated by increasing the thermal conductivity of the second heat dissipating sheets 127 and 137.

The second heat dissipating sheets 127 and 137 may respectively include thermally conductive layers 127a and 137a and cushion layers 127b and 137b. The cushion layers 127b and 137b may be located on a side of the second heat dissipating sheets 127 and 137 facing the chassis 130 or the TCP IC 133, respectively. In this structure, when the surface of the chassis 130 or the TCP IC 133 is not smooth, the second heat dissipating sheets 127 and 137 may closely contact the surface of the chassis 130 or the TCP IC 133, respectively, thereby increasing the heat dissipation performance.

Here, the cushion layers 127b and 137b may be formed as thin as possible within a predetermined range so that the cushion layers 127b and 137b can closely contact the second heat dissipating sheets 127 and 137 to the chassis 130 or the TPC IC 133, respectively. This is because the cushion layers 127b and 137b generally have a lower thermal conductivity than that of the thermally conductive layers 127a and 137a, and therefore, the cushion layers 127b and 137b may reduce the overall heat transfer rate of the second heat dissipating sheets 127 and 137.

Operation of the plasma display module 100 having the heat dissipating sheets 125, 135 and 145 according to an embodiment of the present invention will now be described.

Firstly, when the plasma display module 100 is operating, various circuit devices 121 on the driving circuit substrate 120 apply a voltage to the PDP 110. At this time, the heat generation unit, which includes the PDP 110, the heat generating circuit devices 123, and the TCP IC 133, generates heat.

Heat generated from the PDP 110 may be transferred to the chassis 130 having a relatively low temperature via the heat dissipating sheet 145 located adjacent to the PDP 110. The heat transferred to the chassis 130 may be dissipated into the air by convection.

Some of the heat generated by the heat generating circuit devices 123 may be directly dissipated into the air by convection, while some of the heat may be transferred to the first heat dissipating sheet 125 located adjacent to the driving circuit substrate 120 through the driving circuit substrate 120. Some of the heat transferred to the first heat dissipating sheet 125 may be dissipated into the air by convection, while some of the heat transferred to the first heat dissipating sheet 125 may be further transferred to the chassis 130 and dissipated into the air.

Some of the heat generated from the TCP IC 133 may be directly dissipated into the air or dissipated into the air after being transferred to the cover plate 160 via the second heat dissipating sheet 135 located adjacent to the TCP IC 133. Also, some of the heat may be dissipated into the air from the chassis 130 after the heat is transferred to the reinforcing member 150 directly or via the thermal conductive grease 134 by a thermal conductive action, and afterward, rapidly transferred to the chassis 130.

When the low-molecular-weight siloxane content in the first heat dissipation units 126 and 136 is less than the critical level, e.g., about 5,000 wt ppm, the low-molecular-weight siloxane may barely vaporize. Although a minor amount of the low-molecular-weight siloxane may vaporize, any such vaporized low-molecular-weight siloxane is not sufficient to form an electric insulating layer (not shown) having a thickness that can cause malfunction of the TCP IC 133 and/or the heat generating circuit devices 123.

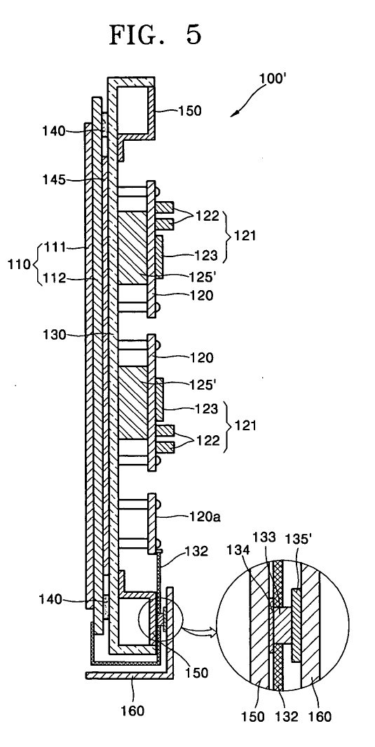

FIG. 5 illustrates a modified version of a plasma display module of FIG. 1 according to an embodiment of the present invention. The differences from FIG. 2 will now be described. In FIGS. 2 and 5, like reference numerals refer to the like elements.

A plasma display module 100′ may include a first heat dissipating sheet 125′ tightly interposed between the driving circuit substrate 120 and the chassis 130 and a second heat dissipating sheet 135′ tightly interposed between the cover plate 160 and the TCP IC 133 for the dissipation of heat generated from the heat generating circuit devices 123 and the TCP IC 133, respectively. The first and second heat dissipating sheets 125′ and 135′ respectively may have the same structure and function as the first heat dissipation units 126 and 136 of FIG. 2. Accordingly, the first and second heat dissipating sheets 125′ and 135′ respectively may have a simple thin structure, thereby reducing manufacturing costs and increasing the heat transfer rate.

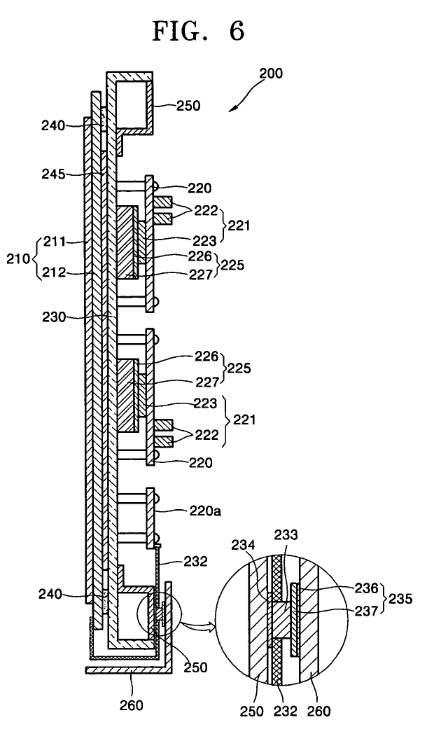

FIG. 6 illustrates a plasma display module 200 according to another embodiment of the present invention.

The plasma display module 200 may include a PDP 210, where an image is displayed, that includes a first panel 211 and a second panel 212, a chassis 230 located on the rear of the PDP 210 to support the plasma display panel 210 and a driving circuit substrate 220 located on the rear of the chassis 230 to drive the PDP 210. A heat dissipating sheet 245 may be interposed between the PDP 210 and the chassis 230, and the PDP 210 and the chassis 230 may be coupled, e.g., by a dual-sided tape 240. Various circuit devices 221 may be mounted on the driving circuit substrate 220 to apply a voltage signal for displaying an image and to supply power to the PDP 210. The circuit devices 221 may include heat generating circuit devices 223 that generate a relatively large amount of heat and ordinary circuits 222 that do not generate a relatively large amount of heat.

The plasma display module 200 differs from the plasma display module 100 in that the heat generating circuit devices 223 that generate relatively a large amount of heat are located on a side of the driving circuit substrate 220 facing the chassis 230. Also, a first heat dissipating sheet 225 for the dissipation of heat generated from the heat generating circuit devices 223 may be directly located between the heat generating circuit devices 223 and the chassis 230. In this structure, the heat generated from the heat generating circuit devices 223 is directly transferred to the chassis 230 through the first heat dissipating sheet 225 without passing through the driving circuit substrate 220, improving the heat dissipation performance.

Referring to FIG. 6, a TCP 232 may electrically connect an address driving unit 220a located on a lower side of the chassis 230 to the plasma display panel 210. The TCP 232 may be supported by a reinforcing member 250 located on the chassis 230 and a TCP IC 233 may be mounted on the TCP 232. The TCP IC 233 may be covered by a cover plate 260, a thermal conductive grease 234 may be located between the TCP IC 233 and the reinforcing member 250, and a second heat dissipating sheet 235 is interposed between the TCP IC 233 and the cover plate 260. The second heat dissipating sheet 235 may transfer heat generated from the TCP IC 233 to the cover plate 260 or may directly dissipates the heat.

The first heat dissipating sheets 225 and 235 may respectively include first heat dissipation units 226 and 236 and second heat dissipation units 227 and 237. The structures, functions and material characteristics of the first heat dissipation units 226 and 236 and second heat dissipation units 227 and 237 are similar to those of the first heat dissipation units 126 and 136 and the second heat dissipation units 127 and 137 of FIG. 2, and thus the descriptions thereof will not be repeated.

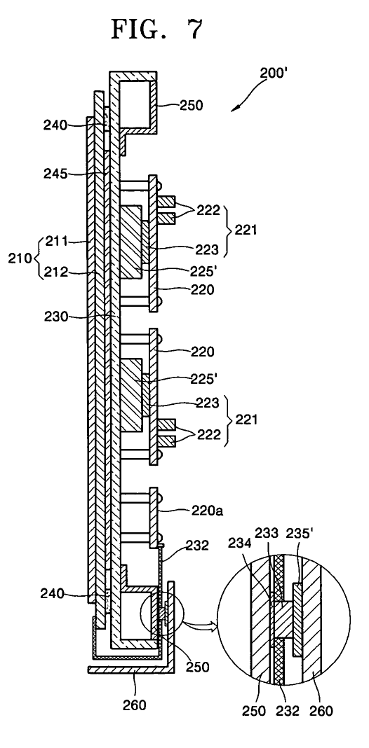

FIG. 7 is a modified version of a plasma display module according to another embodiment of the present invention. The differences from FIG. 6 will now be described. In FIGS. 6 and 7, like reference numerals refer to the like elements.

A plasma display module 200′ may include a first heat dissipating sheet 225′ tightly interposed between the driving circuit substrate 220 and the chassis 230 and the TCP IC 233, and a second heat dissipating sheet 235′ tightly interposed between the cover plate 260 and the TCP IC 233 for the dissipation of heat generated from the heat generating circuit devices 223. The first and second heat dissipating sheets 225′ and 235′ may respectively have the same structure and function as the first heat dissipating sheets 126 and 136 of FIG. 2. Accordingly, the structures of the first and second heat dissipating sheets 225′ and 235′ are thin and simplified, thereby reducing the manufacturing costs and increasing the heat transfer rate.

The plasma display module according to the present invention has the following advantages.

First, heat generated from heat generation unit of the plasma display module may be effectively dissipated.

Second, malfunction of circuit devices caused by the deposition of low-molecular-weight siloxane may be prevented while maintaining a constant heat dissipation effect.

Third, an electrical short of the circuit devices may be prevented when the heat dissipating sheet has an electrical insulation resistance.

Fourth, a plasma display module may have improved heat dissipation effect when locations of the heat generating circuit devices are modified.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A plasma display module comprising:
a plasma display panel;
a chassis for supporting the plasma display panel;
a driving circuit substrate including a plurality of circuit devices located on a side of the chassis to generate electrical signals for driving the plasma display panel; and
a thermally conductive heat dissipating sheet located on a surface of a heat generation unit to dissipate heat generated from the heat generation unit.

2. The plasma display module as claimed in claim 1, wherein the heat dissipating sheet contains low-molecular-weight siloxane in a content of about 5,000 wt ppm or less.

3. The plasma display module as claimed in claim 1, wherein the heat dissipating sheet does not contain low-molecular-weight siloxane.

4. The plasma display module as claimed in claim 1, wherein the heat dissipating sheet comprises a first heat dissipating portion, the first heat dissipating portion including:
a thermally conductive layer on a surface of the heat generation unit; and
an electrically insulating layer surrounding at least a portion of the thermal conductive layer.

5. The plasma display module as claimed in claim 4, wherein the electrically insulating layer has an electrical insulating resistance of at least about 1×10¹⁰ ohm·cm.

6. The plasma display module as claimed in claim 4, wherein the first heat dissipating portion further comprises an adhesive layer to increase adherence to the heat generation unit.

7. The plasma display module as claimed in claim 4, wherein the first heat dissipating portion has a thermal conductivity of at least about 0.1 W/mK.

8. The plasma display module as claimed in claim 4, wherein the first heat dissipating portion includes silicone.

9. The plasma display module as claimed in claim 4, wherein the heat dissipating sheet further comprises a second heat dissipating portion on the first heat dissipating portion and having a different flexibility and thermal conductivity from the first heat dissipating portion.

10. The plasma display module as claimed in claim 9, wherein the second heat dissipating portion has a thermal conductivity of at least about 0.5 W/mK.

11. The plasma display module as claimed in claim 9, wherein the first heat dissipating portion has higher flexibility that the second heat dissipating portion.

12. The plasma display module as claimed in claim 9, wherein the second heat dissipating portion comprises:
a cushion layer; and
a thermally conductive layer on the cushion layer.

13. The plasma display module as claimed in claim 1, wherein the heat dissipation unit is the plasma display panel.

14. The plasma display module as claimed in claim 13, wherein the heat dissipating sheet is between the plasma display panel and the chassis.

15. The plasma display module as claimed in claim 1, wherein the heat dissipating unit is a heat generating circuit device.

16. The plasma display module as claimed in claim 15, wherein the heat dissipating sheet is between a portion of the driving circuit substrate having the heat generating circuit devices and the chassis.

17. The plasma display module as claimed in claim 15, wherein the heat dissipating sheet is between the heat generating circuit devices and the chassis.

18. The plasma display module as claimed in claim 1, further comprising a signal transmitting member for transmitting an electrical signal between the plasma display panel and the driving circuit substrate, the signal transmitting member including an electronic device, wherein the heat generation unit is the electronic device.

19. The plasma display module as claimed in claim 18, wherein the signal transmitting member is a tape carrier package and the electronic device is a tape carrier package integrated circuit.

20. The plasma display module as claimed in claim 18, further comprising a cover plate covering the electronic device, wherein the heat dissipating sheet is between the cover plate and the electronic device.
